(19) United States
(12) Patent Application Publication
(10) Pub. No.: US 2026/0020274 A1
(43) Pub. Date: Jan. 15, 2026

(54) STRUCTURES FOR HIGH ELECTRON MOBILITY TRANSISTOR AND DEPLETION-MODE TRANSISTOR

(71) Applicant: Leadtrend Technology Corporation, Zhubei City (TW)

(72) Inventors: Chih-Yao CHANG, Zhubei City (TW); Cheng-Sheng KAO, Zhubei City (TW); Chih-Wen HSIUNG, Zhubei City (TW)

(21) Appl. No.: 19/240,145

(22) Filed: Jun. 17, 2025

Related U.S. Application Data
(60) Provisional application No. 63/670,136, filed on Jul. 12, 2024.

(51) Int. Cl. H10D 30/47; H10D 64/00

(52) U.S. Cl. CPC H10D 30/471; H10D 64/112

(57) ABSTRACT

A HEMT structure comprises a substrate and a composite semiconductor layer with a heterojunction at which a two-dimensional electron gas is formed. First and second electrodes are electrically connected to the composite semiconductor layer and spaced apart from each other along a first direction. At least two semiconductor isles of a p-type semiconductor are formed directly on the composite semiconductor layer and spaced apart from each other along a second direction perpendicular to the first direction. A gate electrode is on the semiconductor isles and is electrically connected to the semiconductor isles via at least two contact holes. A conductive plate is between the contact holes in view of the second direction and between the gate electrode and the composite semiconductor layer. The conductive plate does not physically contact the composite semiconductor layer.

### CROSS-REFERENCE TO RELATED APPLICATION

This application claims priority to and the benefit of U.S. provisional Application No. 63/670,136 filed on Jul. 12, 2024, which is incorporated by reference in its entirety.

### BACKGROUND

The present disclosure relates generally to structures for high electron mobility transistors, and more particularly to structures for depletion-mode high electron mobility transistors that have conductive plates as field plates.

Because of high-power conversion efficiency and compact product size, switching-mode power supplies are widely favored in the power electronics industry. Generally, a switching-mode power supply includes one or more power switches to control the electrical connection between an input power source and an inductive component. The power switch regulates the inductive component's energy storage from the input power source, as well as the energy released to an output power source. Through this process, the input power from the input power source is converted into the output power, achieving power conversion.

A power switch is typically controlled by a power control circuit. As control techniques become refined and complex, such a power control circuit is often implemented as an integrated circuit, which requires an operational power source. This operational power source must be ready in advance to ensure that the power control circuit controls the power switch properly, allowing the switching-mode power supply to convert electrical energy efficiently.

One method of preparing the operational power supply in a switching-mode power supply is by incorporating a depletion-mode transistor. A depletion-mode transistor naturally possesses a conductive channel even when no bias voltage is applied. In contrast, an enhancement-mode transistor requires a certain bias voltage at its gate to form a conductive channel.

A depletion-mode transistor can be placed between the input power source and the operational power source. When the operational voltage of the operational power source is low, the conductive channel of the depletion-mode transistor automatically conducts current from the input power source to charge the operational power source, increasing the operational voltage. Once the operational voltage reaches a sufficient level, the depletion-mode transistor automatically turns off.

To reduce the number of components in a switching-mode power supply, the depletion-mode transistor can be integrated into the integrated circuit of the power control circuit. However, the depletion-mode transistor must at least withstand the voltage of the input power source. If the input power source has a voltage exceeding 100V for example, integrating the depletion-mode transistor into the integrated circuit will involve several considerations, including IC manufacturing processes, circuit design, and area cost.

### BRIEF DESCRIPTION OF THE DRAWINGS

Non-limiting and non-exhaustive embodiments of the present invention are described with reference to the following drawings. In the drawings, like reference numerals refer to like parts throughout the various figures unless otherwise specified. These drawings are not necessarily drawn to scale. Likewise, the relative sizes of elements illustrated by the drawings may differ from the relative sizes depicted.

The invention can be more fully understood by the subsequent detailed description and examples with references made to the accompanying drawings, wherein:

FIG. 1 demonstrates a HEMT structure according to embodiments of the invention;

FIG. 2 provides a top view of a HEMT structure along the z-direction in FIG. 1;

FIGS. 3A-3C show cross-sectional views along cutlines AA, BB and CC in FIG. 2, respectively;

FIG. 4 illustrates a switching-mode power supply according to embodiments of the invention;

FIG. 5 demonstrates an enhancement-mode transistor;

FIG. 6 illustrates a top view of a HEMT structure according to embodiments of the present invention; and

FIGS. 7A and 7B respectively show cross-sectional views along the cut lines DD and EE in FIG. 6.

### DETAILED DESCRIPTION

In the following description, numerous specific details are set forth in order to provide a thorough understanding of the present invention. It will be apparent, however, to one having ordinary skill in the art that the specific detail need not be employed to practice the present invention. In other instances, well-known materials or methods have not been described in detail in order to avoid obscuring the present invention.

Reference throughout this specification to “one embodiment”, “an embodiment”, “one example” or “an example” means that a particular feature, structure, or characteristic described in connection with the embodiment or example is included in at least one embodiment of the present invention. Thus, appearances of the phrases “in one embodiment”, “in an embodiment”, “one example” or “an example” in various places throughout this specification are not necessarily all referring to the same embodiment or example. Furthermore, the particular features, structures, or characteristics may be combined in any suitable combinations and/or subcombinations in one or more embodiments or examples. Particular features, structures or characteristics may be included in an integrated circuit, an electronic circuit, a combinational logic circuit, or other suitable components that provide the described functionality. In addition, it is appreciated that the figures provided herewith are for explanation purposes to persons ordinarily skilled in the art and that the drawings are not necessarily drawn to scale.

An embodiment of the invention provides a depletion-mode high electron-mobility transistor (HEMT) structure. In this embodiment, the HEMT structure can be integrated with an enhancement-mode HEMT on the same substrate, where the enhancement-mode HEMT serves as a power switch for a switching-mode power supply. This allows both the depletion-mode HEMT structure and the power switch to withstand high input voltages, such as 200V.

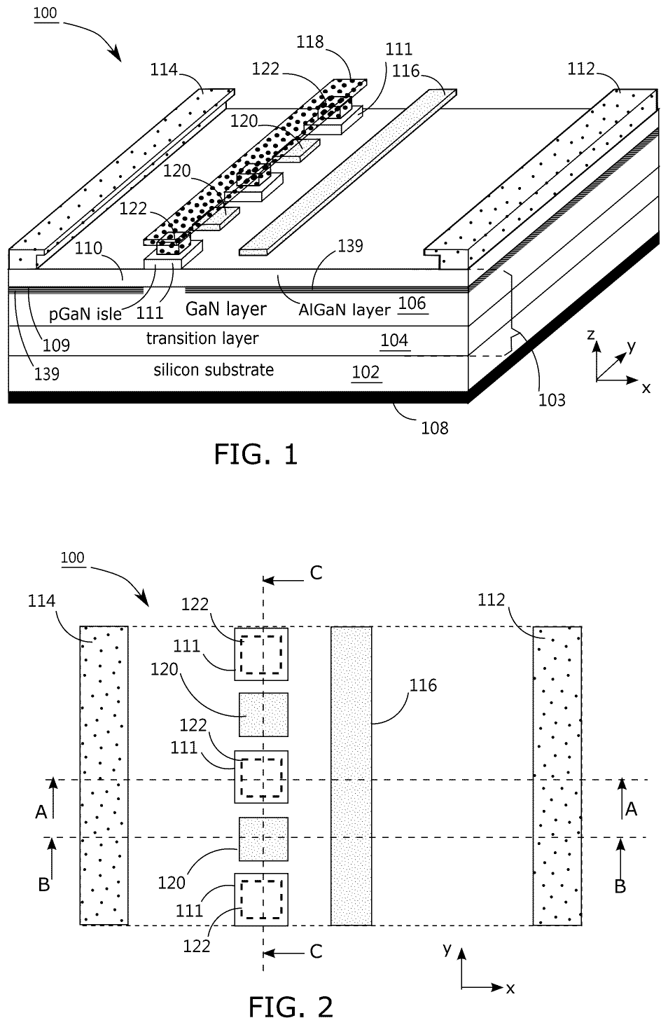

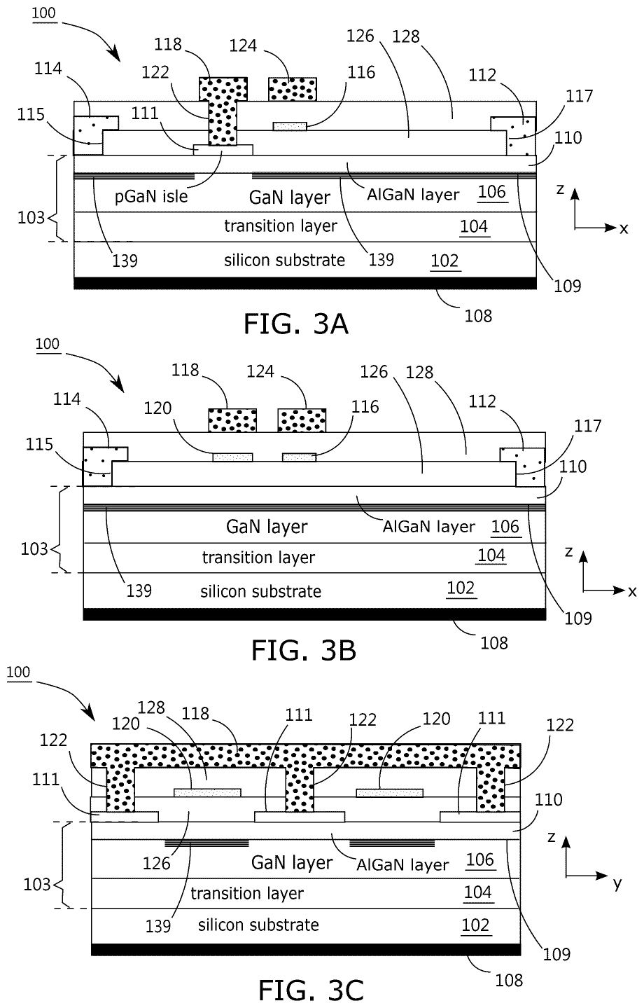

FIG. 1 illustrates a perspective view of HEMT structure 100 implemented according to an embodiment of the invention. FIG. 2 provides a top view of HEMT structure 100 along the z-direction in FIG. 1. FIGS. 3A-3C show cross-sectional views along cutlines AA, BB and CC in FIG. 2, respectively.

Referencing FIG. 1, HEMT structure 100 includes silicon substrate 102, which is a type of semiconductor substrate. Silicone substrate 102 has a bottom surface, underneath which substrate electrode 108, a metal layer for example is formed to provide electrical contact.

On top of silicone substrate 102, composite semiconductor layer 103 is formed, consisting of multiple III-V compound semiconductor layers. As illustrated in FIGS. 1 and 3A-3C, composite semiconductor layer 103 comprises transition layer 104, GaN layer 106, and AlGaN layer 110, which are sequentially stacked on silicon substrate 102. Transition layer 104 may consist of multiple GaN layers with different ratios of Ga to N to reduce stress and defects caused by lattice mismatch between GaN layer 106 and silicon substrate 102. Heterojunction 109 is formed between AlGaN layer 110 and GaN layer 106. Due to polarization effect, two-dimensional electron gas (2DEG) 139 is generated at heterojunction 109, serving as a conductive channel. Semiconductor materials that use electrons as major charge carriers are classified as n-type, while those using holes as major charge carriers are classified as p-type. The 2DEG in an n-type material exhibits high electron mobility, making transistors using this structure known as HEMTs.

As shown in FIGS. 1, 2, 3A, and 3C, several pGaN isles 111, which are examples of p-doped compound semiconductor layers, are formed directly on AlGaN layer 110. pGaN isles 111 physically contact AlGaN layer 110. These pGaN isles 111 are arranged substantially in cutline CC along the y-direction, spaced apart from each other. The material of pGaN isles 111 is a p-type semiconductor, which can reduce or deplete portions of 2DEG 139 at heterojunction 109 that are beneath pGaN isles 111.

Referencing FIGS. 3A-3C, passivation layer 126 is formed over pGaN isles 111. In one embodiment, passivation layer 126 is made of silicon nitride (SiN) and is patterned to form contact holes 115 and 117, as shown in FIGS. 3A and 3B.

Source electrode 114 and drain electrode 112 are formed on passivation layer 126. In one embodiment, these electrodes are made of conductive metal. Source electrode 114 forms an ohmic contact with 2DEG 139 through contact hole 115, and similarly, drain electrode 112 forms another ohmic contact with 2DEG 139 through contact hole 117. Source electrode 114 and drain electrode 112 are spaced apart from each other along the x-direction, as shown in FIGS. 2, 3A and 3B.

Conductive plate 116 and conductive plates 120 are also formed on passivation layer 126. In one embodiment, all are made of TiN and are generated through the same metal deposition, lithography, and etching processes. In one embodiment of the invention, conductive plate 116 and conductive plates 120 do not physically contact each other, or they are spaced apart from one another. As bottomed by passivation layer 126, conductive plate 116 and conductive plates 120 do not physically contact AlGaN layer 110.

As shown in FIGS. 1, 2, 3A, and 3B, conductive plate 116 extends in a strip along the y-direction and is positioned between drain electrode 112 and cutline CC that pGaN islands 111 and conductive plates 120 substantially align to. In one embodiment, conductive plate 116 is electrically floating and acts as a field plate to modulate the electric field distribution in composite semiconductor layer 103, enhancing the drain-to-source breakdown voltage.

Conductive plates 120, as shown in FIGS. 1, 2, 3B, and 3C, are arranged and spaced apart in cutline CC along the y-direction, similar to pGaN islands 111. From FIGS. 2 and 3C, it can be observed that conductive plates 120 and pGaN islands 111 substantially alternate in arrangement and align to cutline CC.

Passivation layer 128 is formed on source electrode 114, drain electrode 112, conductive plate 116, and conductive plates 120. Passivation layer 128 is partially removed, or patterned, to form contact holes 122, as shown in FIGS. 2, 3A, and 3C.

Gate electrode 118 and conductive strip 124 are formed on passivation layer 128. In one embodiment, they are made from the same conductive metal material and manufacturing process flow. As shown in FIGS. 1, 3A, 3B, and 3C, gate electrode 118, like a conductive strip, is substantially positioned above pGaN isles 111 and extends along cutline CC. Through contact holes 122, gate electrode 118 electrically connects to pGaN isles 111 to control their voltage.

In view of clarification, conductive strip 124 is not drawn in FIG. 1, but in FIGS. 3A and 3B. Conductive strip 124 could function as a field plate to adjust the electric field distribution in composite semiconductor layer 103.

As shown along the y-direction in FIG. 3C, each of conductive plates 120 is placed between contact holes 122. Along the z-direction in FIG. 3C, conductive plates 120 are sandwiched by passivation layers 126 and 128, or formed between gate electrode 118 and composite semiconductor layer 103.

HEMT structure 100 provides a depletion-mode HEMT. When external bias voltage is absent, the portions of the 2DEG under pGaN isles 111 are depleted to form depletion regions, but other portions of the 2DEG, such as those under conductive plates 120, still exist to provide electrical connection between source electrode 114 and drain electrode 112. When bias voltage is applied to lower the voltage at gate electrode 118 in respect to the voltages at the source electrode 114 and drain electrode 112, the depletion regions under pGaN isles 111 expand, and adjacent depletion regions may merge to pinch off the connection between source electrode 114 and drain electrode 112, so the depletion-mode HEMT is turned OFF. Accordingly, HEMT structure 100 provides a depletion-mode HEMT whose threshold voltage, the gate-to-source voltage required to turn OFF the HEMT, is negative.

Conductive plates 120 may perform two functions. The first one is to adjust the threshold voltage of the depletion-mode HEMT provided by HEMT structure 100. The second one is to act as a field plate for adjusting the electric field distribution in composite semiconductor layer 103. Although not physically contacted, conductive plates 120 are close to the portions of composite semiconductor layer 103 between the pGaN islands 111. As a result, the voltage at each of conductive plates 120 significantly influences the electrical field below it, determining whether two adjacent depletion regions merge and, consequently, the threshold voltage. For example, it is supposed that HEMT structure 100 has threshold voltages VTH-S and VTH-G when each conductive plate 120 is electrically shorted to source electrode 114 and gate electrode 118, respectively. It can be theoretically concluded that threshold voltage VTHIS is more negative than threshold voltage VTH-G. With proper design in the size, position and electrical connection of conductive plates 120, HEMT structure 100 can produce a depletion-mode HEMT that fits electrical circuit requirements.

The embodiment shown in FIGS. 1 to 3C illustrates that conductive plates 120 are all electrically floating, but the invention is not limited to however. The other embodiment has conductive plates 120 electrically connected to gate electrode 118, and another has them connected to source electrode 114.

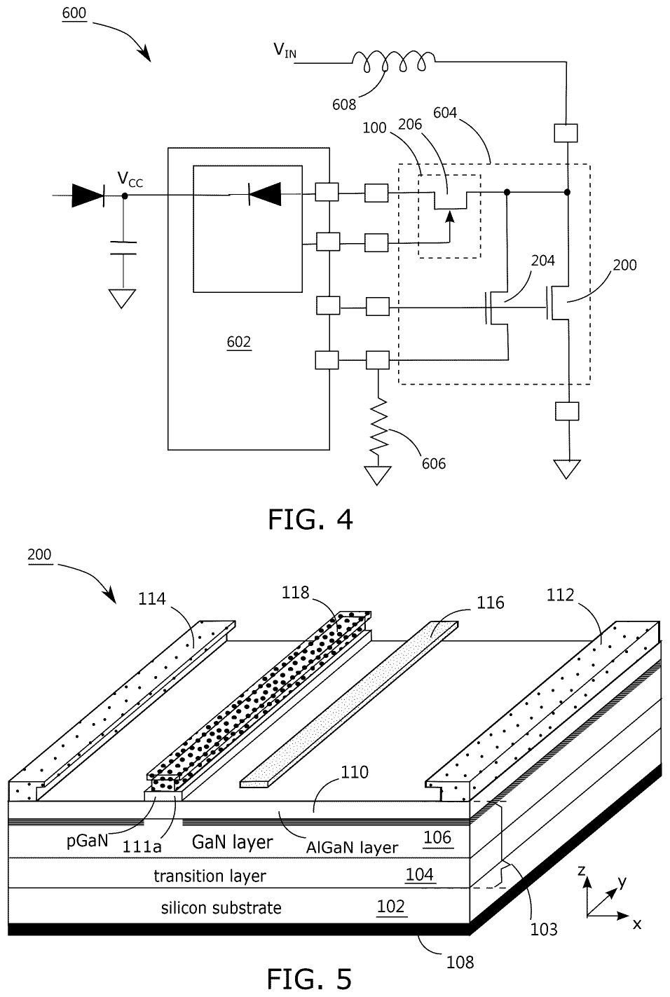

FIG. 4 illustrates switching-mode power supply 600 according to embodiments of the invention. Switching-mode power supply 600 is used to convert input power source V_{IN}, and includes inductor 608, semiconductor chip 604, power controller 602, and current-sensing resistor 606. At least three power switches are formed and integrated in semiconductor chip 604, including depletion-mode HEMT 206 with HEMT structure 100, and two enhancement-mode power switches 204 and 200. When operational voltage V_{CC} is below a predetermined voltage, power switches 204 and 200 are in an OFF state, and depletion-mode HEMT 206 are in an ON state to conduct current via inductor 608, from input power source V_{IN}, so as to increase operational voltage V_{CC}. When operational voltage V_{CC} exceeds the predetermined voltage, depletion-mode HEMT 206 automatically becomes OFF and power controller 602 can work properly.

HEMT structure 100 can be formed within an active region of semiconductor chip 604, where the active region refers to an area made of semiconductor where current can flow and be actively controlled, and is generally defined by a mask used by lithography in a semiconductor process flow. For example, after the formation of drain electrode 112 and source electrode 114 in FIGS. 1, 3A-3C, but before the formation of passivation layer 128, a trench reaching down to silicon substrate 102 can be created around HEMT structure 100 using lithography and etching processes. This trench is then filled up with insulating material, such as silicon oxide, to form an isolation region (not shown). HEMT structure 100 is thus located within an active region surrounded by the isolation region, or the trench with the insulating material. Similarly, power switches 204 and 200 can be formed within another active region enclosed by an isolation region.

FIG. 5 demonstrates power switch 200, an enhancement-mode transistor, that can be formed in an active region of semiconductor chip 604. Power switch 200 in FIG. 5 has features the same or the similar to those in FIGS. 1 to 3C, and thus the same reference numerals are used. Accordingly, power switch 200 in FIG. 5 includes silicon substrate 102, transition layer 104, GaN layer 106, substrate electrode 108, AlGaN layer 110, drain electrode 112, source electrode 114, conductive plate 116, and gate electrode 118. The structure shown in FIG. 5 is also applicable for power switch 204. Unlike pGaN isles 111 in FIGS. 1 to 3C, pGaN strip 111a in FIG. 5 extends continuously in the y-direction without interruption, and separates drain electrode 112 from source electrode 114. When no voltage bias is applied to power switch 200, pGaN strip 111a depletes the portion of the 2DEG underneath it, thereby electrically disconnecting drain electrode 112 from source electrode 114.

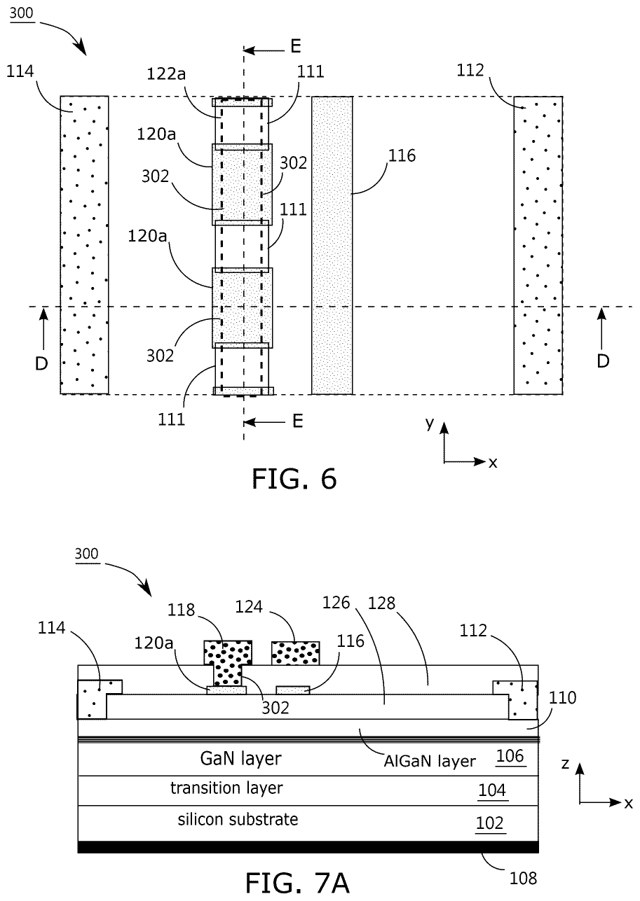

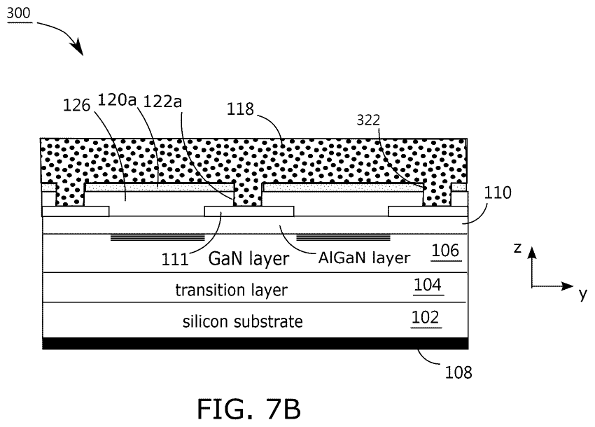

FIG. 6 illustrates HEMT structure 300 according to embodiments of the present invention, while FIGS. 7A and 7B respectively show cross-sectional views along the cut lines DD and EE in FIG. 6. HEMT structure 300 also provides a depletion-mode HEMT. Many features of HEMT structure 300 in FIG. 6 are similar to those in FIGS. 1 to 3C, and therefore, the same reference numerals are used. Accordingly, HEMT structure 300 in FIGS. 6-7B includes silicon substrate 102, transition layer 104, GaN layer 106, substrate electrode 108, AlGaN layer 110, pGaN isles 111, drain electrode 112, source electrode 114, conductive plate 116, gate electrode 118, conductive strip 124, and passivation layers 126 and 128.

As shown in FIG. 7B, although each of conductive plates 120a is positioned approximately above and between two pGaN isles 111, it partially overlaps with the two pGaN isles 111 thereunder. FIGS. 6 and 7A also show trench 302 that extends substantially along cutline EE in the y-direction, where passivation layer 128 has been removed to form trench 302. The process forming trench 302 may also remove a portion of protective layer 126 that is not protected by conductive plates 120a. Therefore, as illustrated in cross-section along trench 302 in FIG. 7B, the bottom of trench 302 is composed by pGaN isles 111 and conductive plates 120a. As a result, trench 302 and conductive plates 120a together define contact holes 122a in FIGS. 6 and 7B. In the top view of FIG. 6, each contact hole 122a is a rectangular with 4 sides, among which two opposite sides are defined by trench 302 while the rest two defined by the edges of conductive plates 120a. Each contact hole 122a has sidewalls 322 and a bottom formed by pGaN isle 111. After trench 302 is filled with the material of gate electrode 118, gate electrode 118 is electrically connected to pGaN isles 111 through contact holes 122a, and is also electrically connected to conductive plates 120a through sidewalls 322 and the upper portions of conductive plates 120a, as shown in FIGS. 7A and 7B. HEMT structure 300 has pGaN isles 111 and conductive plates 120a directly contacted by gate electrode 118, as shown in FIG. 7B.

While the invention has been described by way of examples and in terms of preferred embodiments, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A high-electron-mobility-transistor structure, comprising;
a substrate;
a composite semiconductor layer on the substrate, constructed to have a heterojunction at which a two-dimensional electron gas is formed;
first and second electrodes, both electrically connected to the composite semiconductor layer, wherein the first electrode is spaced apart from the second electrode along a first direction;
at least two semiconductor isles of a p-type semiconductor, formed directly on the composite semiconductor layer, and spaced apart from each other along a second direction perpendicular to the first direction;
a gate electrode, formed above the semiconductor isles and electrically connected to the semiconductor isles via at least two contact holes; and
a conductive plate formed between the contact holes in view of the second direction and between the gate electrode and the composite semiconductor layer, wherein the conductive plate does not physically contact the composite semiconductor layer.

2. The high-electron-mobility-transistor structure of claim 1, wherein the conductive plate is electrically floating.

3. The high-electron-mobility-transistor structure of claim 1, wherein the conductive plate is electrically shorted to the second electrode or the gate electrode.

4. The high-electron-mobility-transistor structure of claim 1, wherein each of the contact holes has a sidewall, through which the gate electrode is electrically connected to the conductive plate.

5. The high-electron-mobility-transistor structure of claim 1, wherein the gate electrode contacts an upper portion of the conductive plate.

6. The high-electron-mobility-transistor structure of claim 1, wherein the composite semiconductor layer comprises a GaN layer and an AlGaN layer, sequentially stacked on the substrate.

7. The high-electron-mobility-transistor structure of claim 1, wherein the conductive plate is made of TiN.

8. The high-electron-mobility-transistor structure of claim 1, wherein the conductive plate is a first conductive plate, and the high-electron-mobility-transistor structure further comprises:
a second conductive plate, electrically floating, and formed between the first electrode and a straight row consisting of the semiconductor isles.

9. The high-electron-mobility-transistor structure of claim 8, wherein the first and second conductive plates are made of the same material, and are spaced apart from each other.

10. The high-electron-mobility-transistor structure of claim 1, further comprising:
a first passivation layer, formed on the composite semiconductor layer and below the conductive plate; and
a second passivation layer, formed on the conductive plate and the first and second electrodes.

11. A depletion-mode high-electron-mobility-transistor structure, comprising;
a composite semiconductor layer formed on a substrate, constructed to provide a conductive channel with a two-dimensional electron gas;
a first electrode formed on the composite semiconductor layer and electrically connected to the conductive channel;
a second electrode formed on the composite semiconductor layer, electrically connected to the conductive channel, and spaced apart from the first electrode in a first direction;
semiconductor isles, formed directly on the composite semiconductor layer and spaced apart from each other in a second direction perpendicular to the first direction;
a gate electrode, formed above the semiconductor isles to contact with the semiconductor isles via at least two contact holes; and
a conductive plate formed between the contact holes in view of the second direction, wherein the conductive plate does not physically contact the composite semiconductor layer;
wherein when an external bias voltage is absent a portion of the two-dimensional electron gas under the semiconductor isles is depleted and another portion of the two-dimensional electron gas under the conductive plate electrically connects the first and second electrodes.

12. The depletion-mode high-electron-mobility-transistor structure of claim 11, wherein the substrate is a silicon substrate, and the composite semiconductor layer comprises a transition layer, a GaN layer, and an AlGaN layer 110, sequentially stacked on the silicon substrate.

13. The depletion-mode high-electron-mobility-transistor structure of claim 11, further comprising:
a first passivation layer, formed on the composite semiconductor layer and below the conductive plate; and
a second passivation layer, formed above the conductive plate and the first and second electrodes.

14. The depletion-mode high-electron-mobility-transistor structure of claim 13, wherein the conductive plate is electrically floating.

15. The depletion-mode high-electron-mobility-transistor structure of claim 13, wherein the conductive plate electrically connects to the gate electrode.

16. The depletion-mode high-electron-mobility-transistor structure of claim 13, wherein the conductive plate is a first conductive plate, the depletion-mode high-electron-mobility-transistor structure further comprises:
a second conductive plate on the first passivation layer, extending in a strip along the second direction and positioned between the first electrode and a straight line that the first conductive plate and the semiconductor isles align to.

17. The depletion-mode high-electron-mobility-transistor structure of claim 13, wherein the first passivation layer is formed on the semiconductor isles, and the conductive plate partially overlaps with the semiconductor isles in a top view.

18. The depletion-mode high-electron-mobility-transistor structure of claim 13, wherein the gate electrode directly contacts the conductive plate and the semiconductor isles.

19. The depletion-mode high-electron-mobility-transistor structure of claim 18, wherein the gate electrode fills a trench extending in the second direction, and the trench has a bottom composed by the conductive plate and the semiconductor isles.

20. The depletion-mode high-electron-mobility-transistor structure of claim 19, wherein each of the contact holes is defined by the trench and the conductive plate.
